(19) United States
(12) Patent Application Publication
(10) Pub. No.: US 2008/0297183 A1
(43) Pub. Date: Dec. 4, 2008

(54) PROBE CARD HAVING COLUMNAR BASE PORTION AND METHOD OF PRODUCING THE SAME

(75) Inventors: Ken YAMAMURA, Fukushima-ken (JP); Shinji MURATA, Fukushima-ken (JP)

Correspondence Address: Beyer Law Group LLP, P.O. BOX 1687, Cupertino, CA, 95015-1687, US

(73) Assignee: ALPS ELECTRIC CO., LTD., Tokyo (JP)

(21) Appl. No.: 12/050,085

(22) Filed: Mar. 17, 2008

(30) Foreign Application Priority Data
May 14, 2007 (JP) 2007-128087

(51) Int. Cl. G01R 1/067; G01R 3/00

(52) U.S. Cl. 324/754; 29/874

(57) ABSTRACT

A probe card includes a flat plate-shaped wiring board, a columnar base portion, and a thee-dimensional spiral contactor. The base portion is interposed between a wiring pattern of the wiring board and the bottom of the contactor.

### CLAIM OF PRIORITY

This application claims benefit of the Japanese Patent Application No. 2007-128087 filed on May 14, 2007, which is hereby incorporated by reference.

### BACKGROUND OF THE INVENTION

1. Field of the Invention

The present invention relates to a probe card and a method of producing the same. In particular, the present invention relates to a probe card that can be suitable for use as a probe card having a three-dimensional spiral contactor and a method of producing the same.

2. Description of the Related Art

In general, in order to check the presence or absence of defects in semiconductor components such as an integrated circuit (IC) and a large-scale integrated circuit (LSI), a probe card is frequently used.

In a general probe card, a continuity test of a semiconductor component is performed by bringing electrodes of a wafer used for the semiconductor component into contact with corresponding contactors of the probe card to check whether the semiconductor component is non-defective or defective. The pitch of the electrode formed on a semiconductor component to be tested has been decreasing year by year. Accordingly, a small contactor pitch has also been desired year by year. Therefore, as shown in FIGS. 10 and 11, a contactor 104 used in a probe card 101 is formed so as to have a three-dimensional spiral shape, which is effective in reducing the pitch.

However, the aspect ratio (the ratio of the height to the diameter) of the three-dimensional spiral contactor 104 depends on the aspect ratio of a resist cone (not shown) that is used as an inner core for forming the contactor 104 in the formation of the contactor 104. Here, it is difficult to change the aspect ratio of the resist cone so as to increase the height of the resist cone from the standpoint of the step of formation. Accordingly, when the diameter of the resist cone is decreased in order to decrease the pitch of the contactor 104, the height of the resist cone is also decreased. More specifically, when the pitch of the contactor 104 is reduced by decreasing the diameter of the resist cone, the amount of movement of the contactor 104 becomes insufficient.

If the amount of movement of the contactor 104 is insufficient, the contactor 104 remains fully contracted without appropriately exerting an elastic force. As a result, a large amount of force is applied to an object to be tested through the contactor 104. Furthermore, when the probe card 101 is pressed onto the object to be tested at an angle, the object contacts an area of a wiring board 102 where no contactors are provided. In such a case, the object to be tested or the wiring board 102 of the probe card 101 may be damaged.

### SUMMARY OF THE INVENTION

Accordingly, the present invention has been made in view of the above points. The present invention provides a probe card in which a large amount of movement of a contactor can be realized even when the diameter of the contactor is decreased, and a method of producing the same.

In addition, the present invention provides a probe card in which damage of an object to be tested and the probe card can be prevented even when a contactor remains fully contracted, and a method of producing the same.

A probe card of a first aspect of the present invention includes a wiring board having a wiring pattern, a columnar base portion made of a conductive material and provided on a surface of the wiring pattern, and a three-dimensional spiral contactor the bottom of which is connected to the surface of the base portion.

According to the probe card of the first aspect of the present invention, the amount of movement can be increased by forming the base portion without changing the diameter or the height of the contactor.

According to a probe card of a second aspect of the present invention, the probe card of the first aspect of the present invention may further include an elastic film, wherein the elastic film is provided on the surface of the wiring board and below the contactor in the form of an elastic material film, and the upper limit of the thickness of the elastic film is the same as the height of the base portion.

According to the probe card of the second aspect of the present invention, by forming the elastic film, when the contactor contacts the elastic film, the elastic film exerts an elastic force on the contactor, thus reducing an impact force applied to an object to be tested or the probe card.

A method of producing a probe card of a first aspect of the present invention includes Step a of forming a resist film using a resin on a surface of a wiring board having a wiring pattern; Step b of forming a columnar through-hole in the resist film to expose the wiring pattern of the wiring board; Step c of forming a columnar base portion using a conductive material on the surface of the wiring pattern exposed in the through-hole of the resist film; Step d of forming a resist cone using a resin without covering the entire surface of the base portion on the surface of the resist film; Step e of forming a seed film on the side face of the resist cone; Step f of applying a resin on the side face of the resist cone having the seed film thereon and on the surface of the base portion, and exposing and developing the resin to form a resist pattern having a spiral groove extending from the base portion; Step g of forming a three-dimensional spiral contactor on the side face of the resist cone which is exposed in the groove of the resist pattern and on which the seed film is provided and on the surface of the base portion such that the base portion serves as the bottom of the contactor; and Step h of removing the resist pattern, a part of the seed film, the part being unnecessary for forming the contactor, the resist cone, and the resist film.

According to the method of producing a probe card of the first aspect of the present invention, the base portion can be easily interposed between the wiring pattern and the contactor without significantly changing a known method of producing a probe card. Accordingly, a probe card in which the amount of movement of a contactor is increased without changing the diameter or the height of the contactor can be easily produced. Consequently, the probe card and the method of producing a probe card according to the first aspect of the present invention are advantageous in that the amount of movement of a contactor can be increased even when the diameter of the contactor is decreased, as compared with a probe card not having a base portion.

A method of producing a probe card of a second aspect of the present invention includes Step a of forming a resist film using a resin on a surface of a wiring board having a wiring pattern; Step b of forming a columnar through-hole in the resist film to expose the wiring pattern of the wiring board; Step c of forming a columnar base portion using a conductive material on the surface of the wiring pattern exposed in the through-hole of the resist film; Step i of baking the resist film after Step b or after Step c; Step d of forming a resist cone using a resin without covering the entire surface of the base portion on the surface of the resist film after Step c and Step i; Step e of forming a seed film on the side face of the resist cone; Step f of applying a resin on the side face of the resist cone having the seed film thereon and on the surface of the base portion, and exposing and developing the resin to form a resist pattern having a spiral groove extending from the base portion; Step g of forming a three-dimensional spiral contactor on the seed film exposed in the groove of the resist pattern and on the surface of the base portion such that the base portion serves as the bottom of the contactor; and Step j of removing the resist pattern, a part of the seed film, the part being unnecessary for forming the contactor, and the resist cone, and leaving the baked resist film as an elastic film on the surface of the wiring board and below the contactor.

According to the method of producing a probe card of the second aspect of the present invention, the base portion can be easily interposed between the wiring pattern and the contactor without significantly changing a known method of producing a probe card. Accordingly, a probe card in which the amount of movement of a contactor is increased without changing the diameter or the height of the contactor can be easily produced. Furthermore, the resist film can be reused as the elastic film without removing the resist film. Accordingly, a probe card including an elastic film that reduces an impact force applied to an object to be tested and the probe card when the contactor contacts the object can be produced. Therefore, even when the contactor remains fully contracted, application of a large impact force on an object to be tested or the probe can be suppressed. Consequently, the probe card and the method of producing a probe card according to the second aspect of the present invention are advantageous in that even when the contractor remains fully contracted, damage of an object to be tested and the probe card can be prevented.

### BRIEF DESCRIPTION OF THE DRAWINGS

FIG. 1 is an enlarged perspective view showing a probe card of a first embodiment;

FIG. 2 is an enlarged front view showing the probe card of the first embodiment;

FIGS. 3A to 3J are longitudinal cross-sectional views showing steps of a method of producing the probe card of the first embodiment in the order of 3A to 3J;

FIG. 4 is an enlarged perspective view showing a probe card of a second embodiment;

FIG. 5 is an enlarged front view showing the probe card of the second embodiment;

FIG. 6 is a longitudinal cross-sectional view showing the probe card of the second embodiment;

FIG. 7 is a graph showing the relationship between the load applied to a contactor and the compression line according to the second embodiment;

FIG. 8 is a longitudinal cross-sectional view showing a probe card of another embodiment;

FIG. 9 is a longitudinal cross-sectional view showing a step of forming a base portion in the probe card of the other embodiment;

FIG. 10 is an enlarged perspective view showing an example of a known probe card; and

FIG. 11 is an enlarged front view showing the example of the known probe card.

### DESCRIPTION OF THE PREFERRED EMBODIMENTS

Probe cards and methods of producing the probe cards will now be described with reference to the drawings using two embodiments.

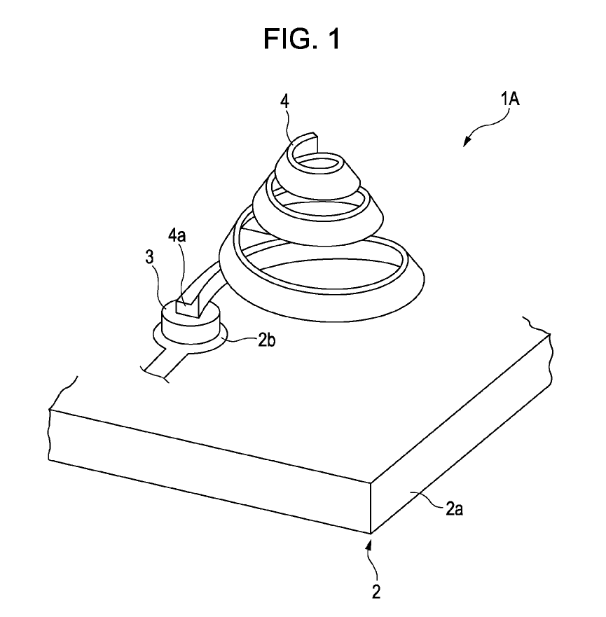

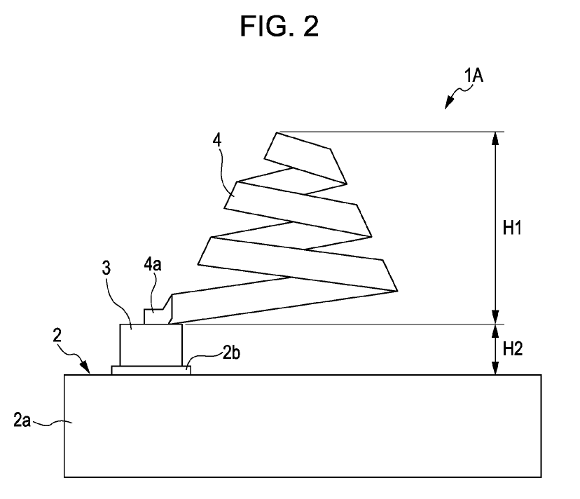

First, a probe card 1A of a first embodiment will be described with reference to FIGS. 1 and 2. FIG. 1 is a perspective view showing the probe card 1A of the first embodiment, and FIG. 2 is a front view showing the probe card 1A of the first embodiment. As shown in FIGS. 1 and 2, the probe card 1A of the first embodiment includes a wiring board 2, a base portion 3, and a contactor 4.

The wiring board 2 includes a wiring substrate 2a formed so as to have a flat-plate shape using an insulating material and a wiring pattern 2b formed on the surface or an inner layer of the wiring substrate 2a using a conductive material. It is sufficient that the wiring pattern 2b is a conductor. Accordingly, the wiring pattern 2b may be a surface electrode shown in FIG. 1 or a via (not shown) extending from an inner layer electrode (not shown) to the surface of the wiring substrate 2a.

The base portion 3 is disposed on the surface of the wiring pattern 2b and formed so as to have a columnar shape using a conductive material. In the first embodiment, the height H2 of this base portion 3 is about 5% to 20% of the height H1 of the contactor 4. As described below, the base portion 3 of the first embodiment is formed so as to have a circular columnar shape by plating using Cu or Ni-P.

The contactor 4 is formed so as to have a three-dimensional spiral shape using a conductive material that easily exhibits an elastic force, such as Ni-P. A bottom 4a of the contactor 4 is connected to the surface of the base portion 3. In the first embodiment, the diameter of the contactor 4 is in the range of 30 to 300 μm, and the height H1 of the contactor 4 is in the range of 30% to 100% of the diameter of the contactor 4.

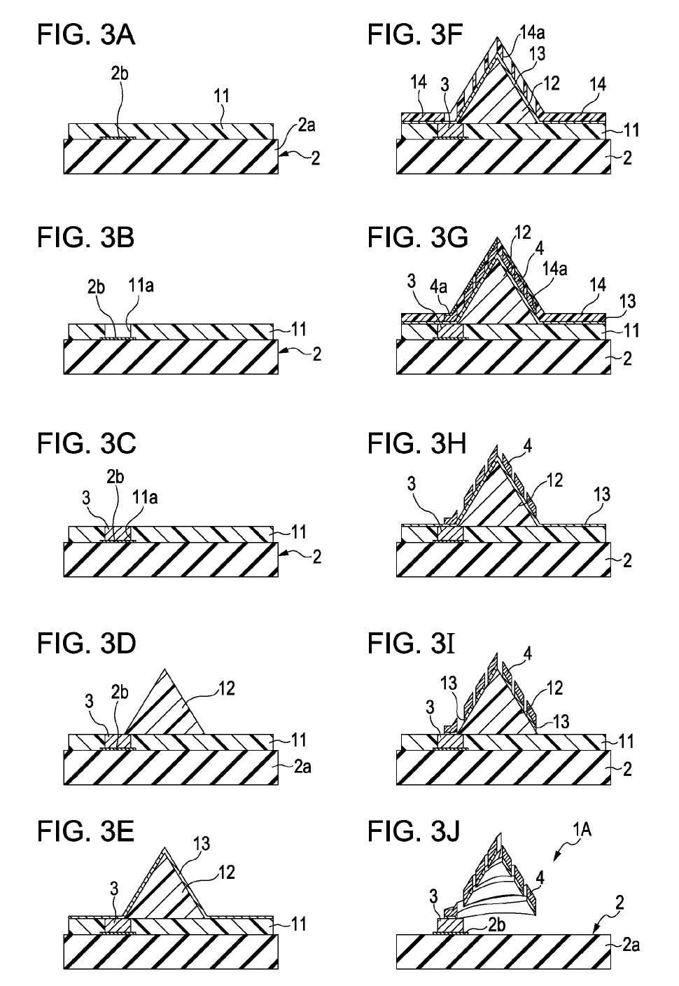

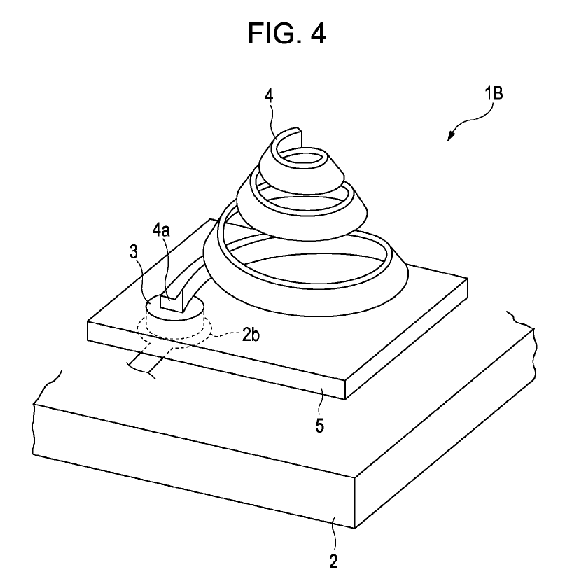

A method of producing the probe card 1A of the first embodiment will now be described with reference to FIGS. 3A to 3J.

FIGS. 3A to 3J are longitudinal cross-sectional views showing steps of the method of producing the probe card 1A of the first embodiment in the order of 3A to 3J. The probe card 1A of the first embodiment is produced by eight steps from Step a to Step h in that order.

In Step a, as shown in FIG. 3A, a resist film 11 made of a resin is formed on the surface of a wiring board 2 having a wiring pattern 2b. In the first embodiment, a photoresist material such as a novolak resin is selected as the resin used in Step a because photoetching is performed in the subsequent step. The thickness of the resist film 11 of the first embodiment is 5% to 20% of the height H1 of the contactor 4.

In step b, as shown in FIG. 3B, the resist film 11 is exposed and developed to form a circular columnar through-hole 11a in the resist film 11. The through-hole 11a is formed at a position on the wiring pattern 2b of the wiring board 2. The wiring pattern 2b is exposed by forming the through-hole 11a. An aqueous solution of tetramethylammonium hydroxide (TMAH) is used as a developer.

In Step c, as shown in FIG. 3C, a circular columnar base portion 3 is formed in the through-hole 11a of the resist film 11 using a conductive material such as Cu or Ni-P. The thickness H2 of the base portion 3 is the same as the thickness of the resist film 11 (the depth of the through-hole 11a). Since the wiring pattern 2b is exposed in the through-hole 11a of the resist film 11, the base portion 3 is formed on the surface of the wiring pattern 2b. By utilizing the wiring pattern 2b as a seed film, the base portion 3 is formed on the surface of the wiring pattern 2b by plating.

In Step d, as shown in FIG. 3D, a resist cone 12 is formed on the surface of the resist film 11 using a resin so as to have a conical shape. The height of the resist cone 12 is in the range of about 30% to 100% of the diameter of a contactor 4. In the first embodiment, the conical resist cone 12 is formed by photoetching with multiple exposure and multiple development. Therefore, a photoresist material is selected as the resin used in Step d. In addition, in order to electrically connect the base portion 3 to the contactor 4 in Step g described below, this resist cone 12 is disposed so as to be adjacent to the base portion 3 without covering the entire surface of the base portion 3. Since it is sufficient that the resist cone 12 does not cover the entire surface of the base portion 3, the base portion 3 of the first embodiment may be partly covered with the resist cone 12, as shown in FIG. 3D.

In Step e, as shown in FIG. 3E, a seed film 13 is formed on at least the side face of the resist cone 12 using a conductive material, such as Cu, having a high conductivity. Since the base portion 3 is conductive, the formation of the seed film 13 on the surface of the base portion 3 is not essential. The seed film 13 of the first embodiment is formed on the side face of the resist cone 12, the surface of the base portion 3, and the surface of the resist film 11.

In Step f, as shown in FIG. 3F, a resin is applied on the side face of the resist cone 12 and the surface of the base portion 3 on which the seed film 13 is provided. A three-dimensional spiral shape is then patterned on the resin, thus forming a resist pattern 14 having a three-dimensional spiral groove 14a. In the first embodiment, the three-dimensional spiral groove 14a is formed by photoetching. Therefore, a photoresist material is selected as the resin used in Step f. In addition, this three-dimensional spiral groove 14a is formed such that the base portion 3 serves as a starting point (i.e., bottom 4a) of the groove 14a. Accordingly, after the formation of the resist pattern 14, the seed film 13 disposed on the surface of the base portion 3 is exposed in the three-dimensional spiral groove 14a.

In Step g, as shown in FIG. 3G, a contactor 4 is formed on the surface of the seed film 13 exposed on the groove 14a of the resist pattern 14 by plating using an elastic metal material such as Ni-P. The height H1 of the contactor 4 is the same as the height of the resist cone 12 having the resist pattern 14 on the side face thereof. Since the shape of the groove 14a of the resist pattern 14 is a three-dimensional spiral shape, the shape of this contactor 4 is also a three-dimensional spiral shape. In addition, the three-dimensional spiral groove 14a of the resist pattern 14 is provided such that the surface of the base portion 3 covered with the seed film 13 serves as a starting point of the groove 14a. Therefore, the contactor 4 is also formed such that the surface of the base portion 3 covered with the seed film 13 serves as the starting point (bottom 4a) of the contactor 4.

In Step h, as shown in FIGS. 3H to 3J, the resist pattern 14, a part of the seed film 13, the part being unnecessary for forming the contactor 4, the resist cone 12, and the resist film 11 are removed. Specifically, first, as shown in FIG. 3H, the resist pattern 14 is removed using a resist remover. N-methyl-2-pyrrolidone (molecular formula: C₅H₉NO, trade name: NMP) is used as the resist remover. Next, as shown in FIG. 3I, the seed film 13 exposed by removing the resist pattern 14 (a part of the seed film 13, the part being unnecessary for forming the contactor 4) is removed by ion milling. Finally, as shown in FIG. 3J, the resist cone 12 and the resist film 11 are removed using the same resist remover as that mentioned above. The probe card 1A of the first embodiment is produced by Step a to Step h above.

Operations of the probe card 1A of the first embodiment and the method of producing the probe card 1A will now be described with reference to FIGS. 1 and 2.

As described above, the probe card 1A of the first embodiment includes the wiring board 2, the base portion 3, and the contactor 4, as shown in FIGS. 1 and 2. The base portion 3 is interposed between the wiring pattern 2b of the wiring board 2 and the bottom 4a of the contactor 4 having a three-dimensional spiral shape. Therefore, the amount of movement of the contactor 4 is a value calculated by adding the height H2 of the base portion 3 to the height H1 of the contactor 4. That is, the probe card 1A includes the base portion 3 interposed between the wiring board 2 and the contactor 4. As a result, the amount of movement of the contactor 4 can be increased by a length corresponding to the height H2 of the base portion 3 without changing the diameter or the height of the contactor 4.

Since the height H2 of the base portion 3 is in the range of 5% to 20% of the height H1 of the contactor 4, the amount of stoke of the contactor 4 is increased by about 5% to 20%. Accordingly, in the three-dimensional spiral contactor 4 whose aspect ratio is difficult to change, even when the height of the base portion 3 is small, the amount of movement of the contactor 4 can be markedly increased.

As described above, the probe card 1A of the first embodiment is produced by Step a to Step h, as shown in FIGS. 3A to 3J. As shown in FIGS. 3A to 3C, in Step a to Step c, the through-hole 11a is formed in the resist film 11 provided on the surface of the wiring board 2, and the base portion 3 is formed in the through-hole 11a by plating. Thus, the base portion 3 can be easily formed. In addition, as shown in FIG. 3D to 3J, in Step d to the subsequent steps, the contactor 4 is produced by the same method as the method of producing the known probe card 101. Therefore, according to the method of producing the probe card 1A of the first embodiment, the base portion 3 can be formed between the wiring pattern 2b and the contactor 4 without significantly changing the method of producing the known probe card 101. Accordingly, the probe card 1A having an increased amount of movement can be easily produced without changing the diameter or the height of the contactor 4.

That is, according to the probe card 1A of the first embodiment, by forming the base portion 3, the amount of movement of the contactor 4 can be increased without changing the diameter or the height of the contactor 4. In addition, according to the method of producing the probe card 1A of the first embodiment, the base portion 3 can be easily formed between the wiring pattern 2b and the contactor 4. Accordingly, the probe card 1A and the method of producing the probe card 1A are advantageous in that even when the diameter of the contactor 4 is small, the amount of movement can be increased, as compared with the known probe card 101 not including a base portion 3.

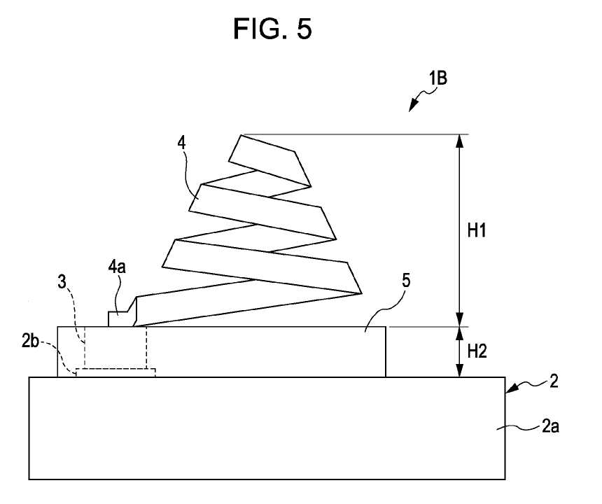

Next, a probe card 1B of a second embodiment will now be described with reference to FIGS. 4 and 5. FIG. 4 is a perspective view showing the probe card 1B of the second embodiment, and FIG. 5 is a front view showing the probe card 1B of the second embodiment. As shown in FIGS. 4 and 5, the probe card 1B of the second embodiment includes a wiring board 2, a base portion 3, an elastic film 5, and a contactor 4. The probe card 1B of the second embodiment differs from the probe card 1A of the first embodiment in that the elastic film 5 is provided. The wiring board 2, the base portion 3, and the contactor 4 are formed as in the first embodiment.

The elastic film 5 is provided on the surface of the wiring board 2 and below the contactor 4 in the form of a film using an elastic material. Any material, such as rubber or a resin, may be selected as the elastic material used for the elastic film 5 as long as the material exhibits a large elastic force against an external force. A photoresist material such as a novolak resin is used as the elastic material of the second embodiment. This is because a resist film 11 used in the formation of the base portion 3 is used as the elastic film 5 without further treatment. The thickness of the elastic film 5 is determined so that the height H2 of the base portion 3 is the upper limit of the thickness of the elastic film 5. The height H2 of the base portion 3 is in the range of 5% to 20% of the height H1 of the contactor 4. The thickness of the elastic film 5 does not exceed the height H2 of the base portion 3.

The probe card 1B of the second embodiment is formed by nine steps of Step a to Step c, Step i, Step d to Step g, and Step j in that order. Step a to Step c and Step d to Step g are the same as the first embodiment. Step i and Step j are different from the first embodiment. Accordingly, these steps will now be described with reference to FIGS. 3A to 3G showing the steps of the method of producing the probe card 1A of the first embodiment.

In Step a, as shown in FIG. 3A, a resist film 11 made of a resin is formed on the surface of a wiring board 2 having a wiring pattern 2b. As in the first embodiment, a photoresist material such as a novolak resin is selected as the resin. The thickness of the resist film 11 is 5% to 20% of the height H1 of the contactor 4 as in the first embodiment.

In step b, as shown in FIG. 3B, a columnar through-hole 11a is formed in the resist film 11 to expose a wiring pattern 2b of the wiring board 2. In step c, as shown in FIG. 3C, a columnar base portion 3 is formed on the surface of the wiring pattern 2b exposed in the through-hole 11a of the resist film 11 using a conductive material.

In Step i, in the state shown in FIG. 3C, the resist film 11 is baked after the formation of the base portion 3 (after Step c). When the resist film 11 is baked after the formation of the base portion 3, the base portion 3 is also heated. Accordingly, in the case where the thermal effect on the base portion 3 is considered, the resist film 11 may be baked before the formation of the base portion 3 (after Step b).

In Step d, as shown in FIG. 3D, after the formation of the base portion 3 (after Step c) and after the baking of the resist film 11 (after Step i), a resist cone 12 is formed on the surface of the resist film 11 using a resin. As in the first embodiment, it should be noted that the resist cone 12 does not cover the entire surface of the base portion 3. In step e, as shown in FIG. 3E, a seed film 13 is formed on the side face of the resist cone 12, the surface of the base portion 3, and the surface of the resist film 11.

In Step f, as shown in FIG. 3F, a resist pattern 14 having a spiral groove 14a is formed. This resist pattern 14 is formed by applying a resin on the surface of the seed film 13, and then performing multiple exposure and multiple development of the resin. As in the first embodiment, the three-dimensional spiral groove 14a is formed such that the base portion 3 serves as a starting point of the groove 14a.

In Step g, as shown in FIG. 3G, a three-dimensional spiral contactor 4 is formed on the surface of the seed film 13 exposed in the groove 14a of the resist pattern 14 by plating, for example, Ni-P. As in the first embodiment, a bottom 4a of the contactor 4 is connected to the base portion 3.

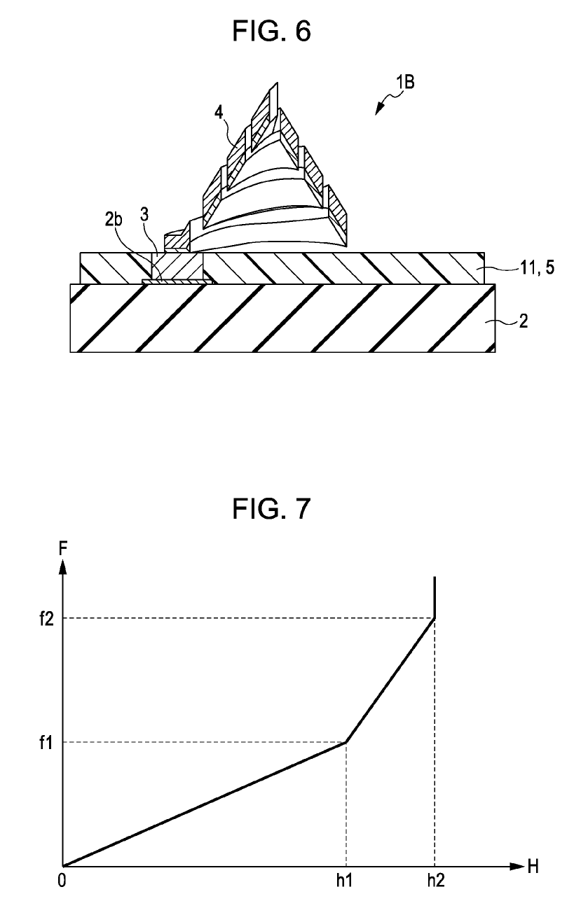

In Step j, as shown in FIGS. 3H and 3I and FIG. 6, the resist pattern 14 is removed (refer to FIG. 3H), a part of the seed film 13, the part being unnecessary for forming the contactor 4, is removed (refer to FIG. 3I), and the resist cone 12 is removed using a resist remover (refer to FIG. 6). The baked resist film 11 is a resist material such as a novolak resin, and thus the resist film 11 exerts an elastic force. Accordingly, as shown in FIG. 6, unlike the first embodiment (refer to FIG. 3J), the resist film 11 is left on the surface of the wiring board 2 and below the contactor 4 as an elastic film 5. This resist film 11 is not easily removed even when the resist remover is used because the resist film 11 has been baked. Therefore, the resist film 11 is not simultaneously removed during the removal of the resist cone 12. The probe card 1B of the second embodiment is produced by the above steps.

Operations of the probe card 1B of the second embodiment and the method of producing the probe card 1B will now be described with reference to FIGS. 4 to 7.

As shown in FIGS. 4 and 5, the probe card 1B of the second embodiment includes the wiring board 2, the base portion 3, the contactor 4, and the elastic film 5. As in the first embodiment, the base portion 3 is interposed between the wiring board 2 and the contactor 4. Therefore, the amount of movement of the contactor 4 is a value calculated by adding the height H2 of the base portion 3 to the height H1 of the contactor 4. That is, the position of the bottom of the contactor 4 is elevated by a length corresponding to the height H2 of the base portion 3. As a result, the amount of movement of the contactor 4 can be increased without changing the diameter or the height of the contactor 4.

Furthermore, in the probe card 1B of the second embodiment, the elastic film 5 is disposed on the surface of the wiring board 2 and below the contactor 4. When the contactor 4 contacts the elastic film 5, the modulus of elasticity of the contactor 4 is increased by an amount corresponding to the modulus of elasticity of the elastic film 5.

FIG. 7 is a graph showing the relationship between the load applied to the contactor 4 and the compression line. For example, when a load f1 is applied to the contactor 4 and the contactor 4 moves by an amount of h1, the contactor 4 contacts the elastic film 5. Furthermore, as shown in FIG. 7, when the contactor 4 moves from h1 to h2, a large elastic force is applied from the elastic film 5 to the contactor 4.

That is, since the elastic film 5 is interposed between the contactor 4 and the wiring board 2, the elastic film 5 functions as a buffer material and prevents a large impact force from being applied from the contactor 4 to the wiring board 2. Therefore, an impact force applied to an object to be tested, such as a semiconductor component, and the probe card 1B on which the contactor 4 is provided can be reduced.

The probe card 1B of the second embodiment is formed by nine steps of Step a to Step c, Step i, and Step d to Step g, and Step j in that order. Among these steps, Step i and Step j differ from the steps in the first embodiment. Since the resist film 11 is baked in Step i in the second embodiment, as shown in FIGS. 3I and 6, the baked resist film 11 is not removed by a resist remover during the removal of the resist cone 12 in Step j. Therefore, as shown in FIG. 6, the resist film 11 for forming the base portion 3 can be reused as the elastic film 5 without removal and without further treatment. Accordingly, this method is environmentally friendly, and a step of forming the elastic film 5 need not be separately and independently performed.

According to the probe card 1B of the second embodiment, in addition to the operations obtained by the probe card 1A of the first embodiment, the following operation can be achieved. Specifically, by forming the elastic film 5, when the contactor 4 contacts the elastic film 5, the elastic film 5 exerts an elastic force on the contactor 4. Furthermore, according to the method of producing the probe card 1B, the resist film 11 can be reused as the elastic film 5. Accordingly, in addition to the operations obtained by the probe card 1A of the first embodiment and the method of producing the probe card 1A, an application of a large impact force to an object to be tested or the probe card can be suppressed even when the contactor 4 remains fully contracted. Accordingly, this method can provide an operation that damage of the object to be tested or the probe card can be prevented even when the contactor 4 remains fully contracted.

The present invention is not limited to, for example, the above-described embodiments, and various modifications can be made according to need.

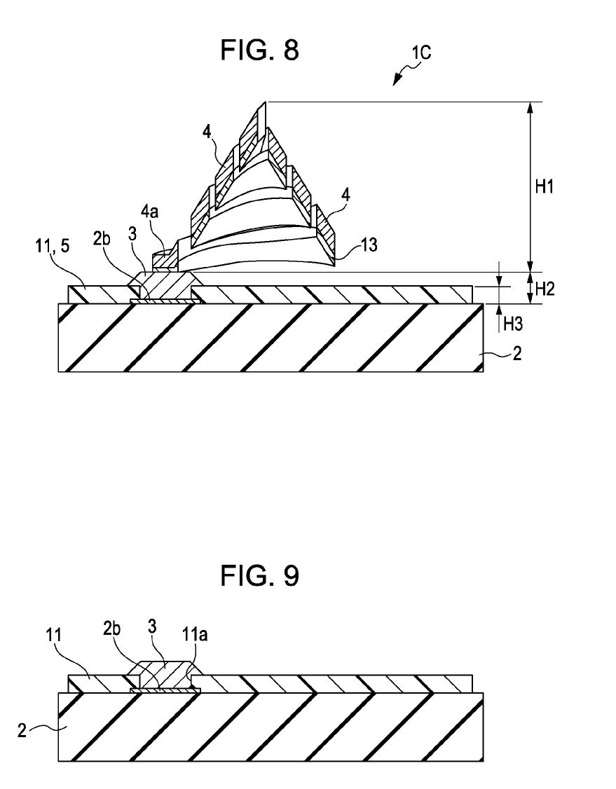

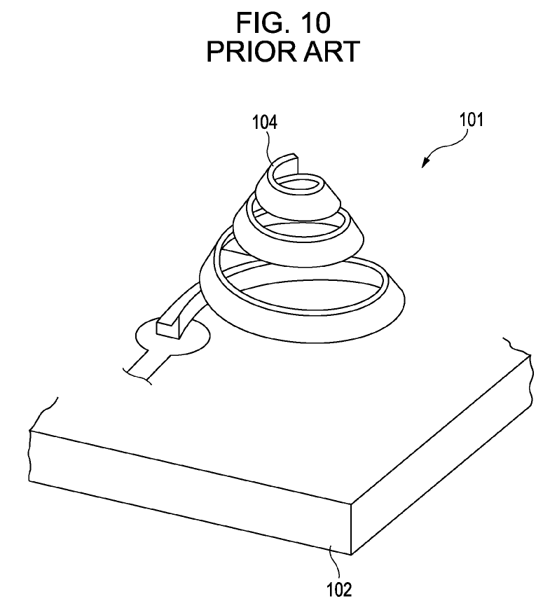

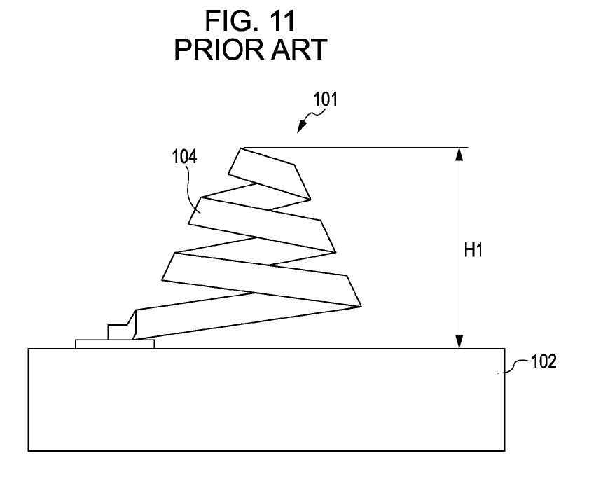

For example, as shown in FIG. 6, in the probe card 1B of the second embodiment, the height H2 of the base portion 3 is the same as the thickness of the elastic film 5. Alternatively, in a probe card 1C of another embodiment, as shown in FIG. 8, the thickness H2 of a base portion 3 may be larger than the thickness H3 of an elastic film 5. In this case, the base portion 3 higher than the thickness H3 of the elastic film 5, that is, the elastic film 5 having a thickness smaller than the height of the base portion 3 can be produced as follows. In the step of forming the base portion 3 shown in FIG. 3C (Step c), as shown in FIG. 9, plating is performed for a long time to form the base portion 3 inside a through-hole 11a such that the thickness of the base portion 3 is larger than the thickness H3 of a resist film 11 (elastic film 5). In this case, the base portion 3 is formed so as to have a mushroom shape because the plating film extends on the surface of the resist film 11 (elastic film 5). However, since the position of the bottom of the contactor 4 is elevated, the base portion 3 does not adversely affect the performance of the contactor 4 even though the base portion 3 having a mushroom shape is formed.

The contactors 4 of the first embodiment and the second embodiment are formed by metal plating. Alternatively, a contactor 4 of another embodiment may be made of an insulating material, such as a ceramic material or silicon, which can exert an elastic force larger than that obtained by Ni-P. In such a case, a conducting portion is formed on the surface of the insulating material having a shape similar to the three-dimensional spiral contactor 4 by metal plating or the like. Thus, a conductive contactor 4 can be formed.

What is claimed is:

1. A probe card having a columnar base portion, comprising:
a wiring board having a wiring pattern;
a columnar base portion made of a conductive material and provided on a surface of the wiring pattern; and
a three-dimensional spiral contactor the bottom of which is connected to the surface of the base portion.

2. The probe card having a columnar base portion according to claim 1, further comprising:
an elastic film,
wherein the elastic film is provided on the surface of the wiring board and below the contactor in the form of an elastic material film, and the upper limit of the thickness of the elastic film is the same as the height of the base portion.

3. A method of producing a probe card having a columnar base portion, comprising:
Step a of forming a resist film using a resin on a surface of a wiring board having a wiring pattern;
Step b of forming a columnar through-hole in the resist film to expose the wiring pattern of the wiring board;
Step c of forming a columnar base portion using a conductive material on the surface of the wiring pattern exposed in the through-hole of the resist film;
Step d of forming a resist cone using a resin without covering the entire surface of the base portion on the surface of the resist film;
Step e of forming a seed film on the side face of the resist cone;
Step f of applying a resin on the side face of the resist cone having the seed film thereon and on the surface of the base portion, and exposing and developing the resin to form a resist pattern having a spiral groove extending from the base portion;
Step g of forming a three-dimensional spiral contactor on the seed film exposed in the groove of the resist pattern and on the surface of the base portion such that the base portion serves as the bottom of the contactor; and
Step h of removing the resist pattern, a part of the seed film, the part being unnecessary for forming the contactor, the resist cone, and the resist film.

4. A method of producing a probe card having a columnar base portion, comprising:
Step a of forming a resist film using a resin on a surface of a wiring board having a wiring pattern;
Step b of forming a columnar through-hole in the resist film to expose the wiring pattern of the wiring board;
Step c of forming a columnar base portion using a conductive material on the surface of the wiring pattern exposed in the through-hole of the resist film;
Step i of baking the resist film after Step b or after Step c;
Step d of forming a resist cone using a resin without covering the entire surface of the base portion on the surface of the resist film after Step c and Step i;
Step e of forming a seed film on the side face of the resist cone;
Step f of applying a resin on the side face of the resist cone having the seed film thereon and on the surface of the base portion, and exposing and developing the resin to form a resist pattern having a spiral groove extending from the base portion;
Step g of forming a three-dimensional spiral contactor on the side face of the resist cone which is exposed in the groove of the resist pattern and on which the seed film is provided and on the surface of the base portion such that the base portion serves as the bottom of the contactor; and
Step j of removing the resist pattern, a part of the seed film, the part being unnecessary for forming the contactor, and the resist cone, and leaving the baked resist film as an elastic film on the surface of the wiring board and below the contactor.
